(19) United States
(12) Patent Application Publication
(10) Pub. No.: US 2023/0282466 A1
(43) Pub. Date: Sep. 7, 2023

(54) SPUTTER MAGNETRON FOR OPERATING WITH OTHER PLASMA SOURCES

(71) Applicant: LI QIN ZHOU, Okemos, MI (US)

(72) Inventor: LI QIN ZHOU, Okemos, MI (US)

(73) Assignee: SCION PLASMA LLC, East Lansing, MI (US)

(21) Appl. No.: 17/687,673

(22) Filed: Mar. 6, 2022

(51) Int. Cl. H01J 37/34; C23C 14/34; C23C 14/35

(52) U.S. Cl. CPC H01J 37/3405; H01J 37/3441; C23C 14/3442; H01J 37/3461; H01J 37/3452; C23C 14/351; H01J 2237/332

(57) ABSTRACT

A sputtering magnetron apparatus is provided. Another aspect employs a set of magnet assembly that forms a magnetic field over the target surface to confine electrons. A further aspect of a sputtering magnetron includes a side dark space shield that is made of magnetic metal which shunts the magnetic flux leaking from the side to prevent the formation of a secondary plasma around the dark space shield when it operates simultaneously with another plasma source.

### BACKGROUND AND SUMMARY

The present application generally pertains to a sputtering magnetron and more particularly to a sputtering magnetron that simultaneously operates with ion sources or other plasma sources for thin film deposition.

Magnetron sputtering is widely used for manufacturing thin films for semiconductor devices, displays, solar panels, tribological coatings, sensors, and micro-electro-mechanical systems. Conventional magnetron sputtering generally results in loosely packed atoms, as shown in FIG. 1, due to their unfavorable kinetic energies. The micro-porous structures lead to unstable material properties and device performance. Ion beam assisted magnetron sputtering can overcome the limitations of conventional magnetron sputtering and has been widely used for manufacturing high-quality thin films and devices.

Magnetron sputtering is realized by applying a negative voltage bias −V_{T} to the cathode/target in combination with a static magnetic field, as illustrated in FIG. 2. The negative voltage bias attracts positively charged ions from the plasma to strike the target, causing sputtering of the target atoms that are subsequently deposited on a working piece (substrate). The magnetic field plays a critical role in effectively confining the energetic electrons and enhancing the gas ionization, leading to increased plasma density and high deposition rates. An essential component in a sputtering magnetron is a dark-space shield that is connected to ground potential to prevent the formation of plasma in regions other than the target.

On the other hand, ion sources are excited with a positive voltage bias −V_{I} that drives positively charged ions out of the sources. In the ion beam assisted sputtering illustrated in FIG. 3, the ions interact with the sputtered atoms as they are deposited on a working piece. The microstructure of the deposited film can be subsequently modulated by the ion energy. The ion beam assisted deposition can produce dense films with smooth surfaces, which are highly desirable for numerous applications.

When a conventional sputtering magnetron simultaneously operates with an ion source, an undesirable secondary plasma is generated as illustrated in FIG. 4. This secondary plasma appears around the dark-space shield and causes sputtering of the shield, leading to contamination of the deposited films, This secondary plasma is generated due to two main reasons. First, there is a potential difference between the ion source and the magnetron dark-space shield. Relative to the ion source, the dark-space shield is at a lower potential. Second, there is a secondary magnetic field leaking from the magnet assembly of the sputtering magnetron, as illustrated in FIG. 5. This secondary magnetic field forms a closed loop around the dark-space shield and can confine electrons. Under the influence of the ion source potential, a secondary plasma is subsequently generated.

In accordance with the present invention, a sputtering magnetron is provided. A further aspect of a sputtering magnetron includes a dark-space shield made of magnetic steel that can effectively eliminate the leaked magnetic field from a conventional magnetron. In another aspect, the magnet assembly in the magnetron is optimized to deliver an appropriate magnetic field in front of the target to realize effective sputtering deposition.

The present sputtering magnetron is advantageous over traditional devices. No secondary plasma is created when it simultaneously operates with an ion source. Hence, contamination of the film is eliminated. Additional features and benefits will become apparent from the following description and appended claims taken in conjunction with the accompanying drawings.

### BRIEF DESCRIPTION OF THE DRAWINGS

FIG. 1 is a diagrammatic cross-sectional view showing coating atoms on a workpiece without the assistance of an ion beam;

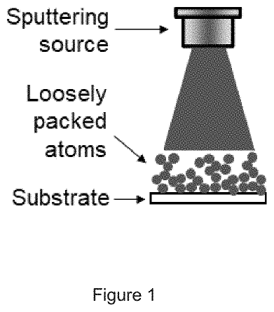

FIG. 2 is a diagrammatic cross-sectional view showing the prior art sputtering magnetron;

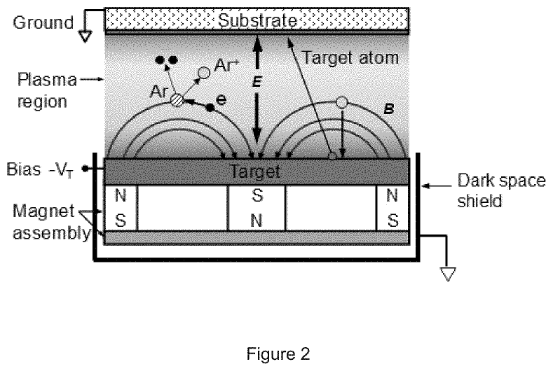

FIG. 3 is a diagrammatic view showing a configuration of ion beam assisted magnetron sputtering;

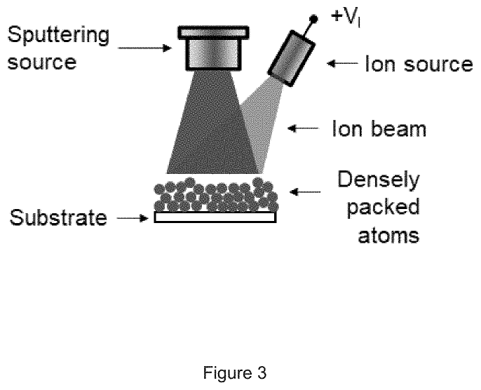

FIG. 4 is a photo showing a secondary plasma created during ion beam enhanced sputtering using prior art sputtering magnetron;

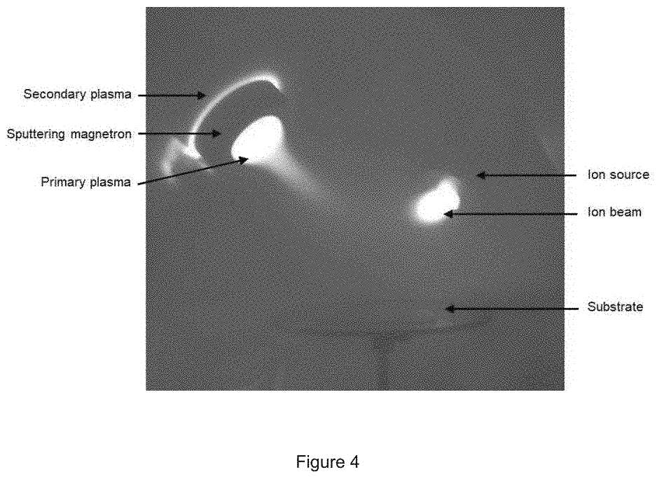

FIG. 5 is a cross-sectional view showing the magnetic field flux from the prior art sputtering magnetron;

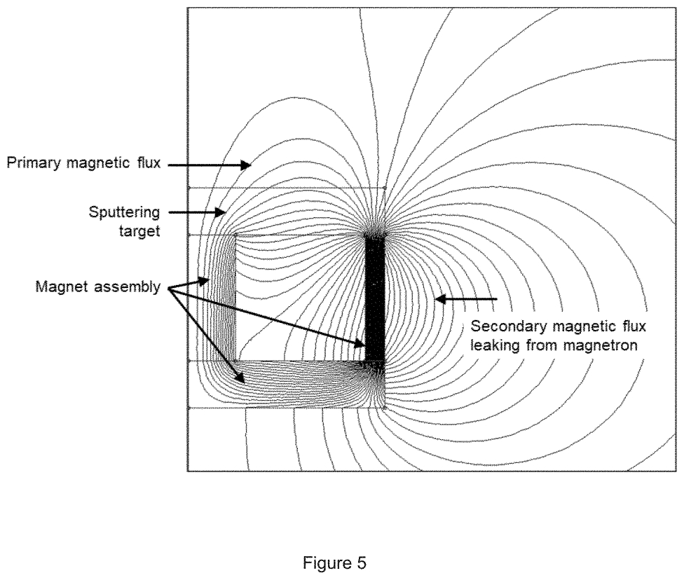

FIG. 6 is a cross-sectional view showing the magnetic field flux from the present sputtering magnetron;

FIG. 7 is a cross-sectional view showing the present sputtering magnetron;

FIG. 8 is a photo showing no secondary plasma is created during ion beam enhanced sputtering using the present sputtering magnetron;

FIG. 9 is a cross-sectional view showing the magnetic field flux from the present sputtering magnetron.

### DETAILED DESCRIPTION

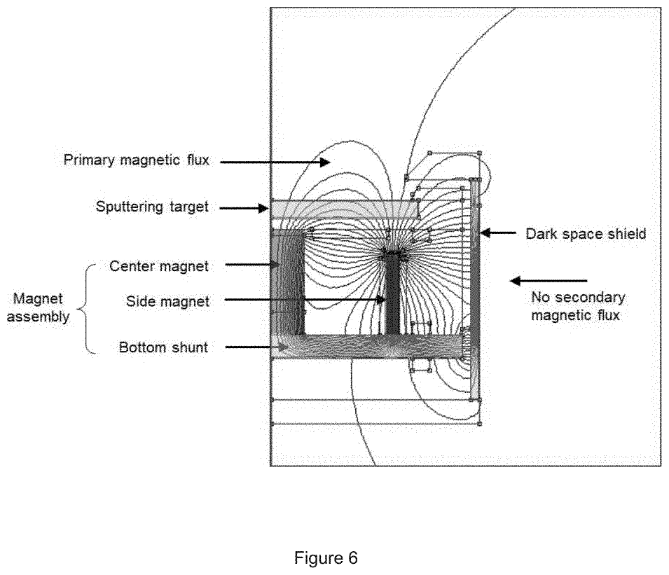

A preferred embodiment of the magnetic flux in a sputtering magnetron can be observed in FIG. 6. There is only a primary magnetic flux, above a sputtering target, being created by a magnet assembly. A dark space shield effectively shunts the leaking flux around the side. Therefore, no substantial secondary magnetic flux exists outside the shield to effectively confine electrons around the shield. The dark space shield is made of magnetic steel such as stainless steel 400 series and carbon steel. The magnet assembly includes at least a center magnet and a side magnet with N-S polarity in opposite directions. In an embodiment of the magnet assembly, a bottom shunt made of magnetic steel can be used. The center magnet and side magnet are placed on top of this bottom shunt. A complete sputtering magnetron based on this preferred embodiment of the magnetic flux also includes other components, as described below.

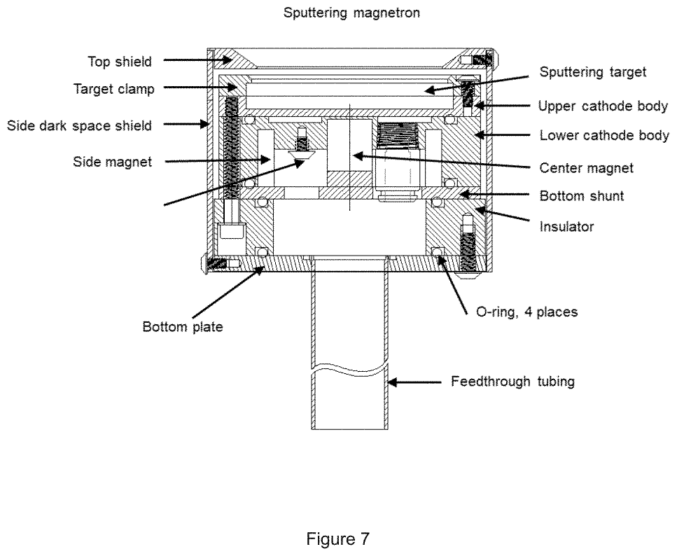

An exemplary sputtering magnetron is illustrated in FIG. 7. A center magnet and a side magnet are set on a bottom shunt. The side magnet can be one single ring magnet or multiple small rod-shaped magnets. The bottom shunt extends beyond the side magnet and is in adjacent to a side dark space shield. The side dark space shield is made of magnetic steel. The gap between the dark space shield and the bottom shunt is preferably in the range of 1-5 mm. A target is set on top of a cathode body and a clamp is set on top of the cathode body and holds the target in place. The cathode body includes an upper cathode body and a lower cathode body sealed with an O-ring. Two water feedthroughs are connected to the lower cathode body and allow cooling water to flow through the cathode cooling channel. An electric contact screw connected to the lower cathode body is used to connect a power cable. A second O-ring is used to seal the lower cathode body and the bottom shunt. The target, cathode body, and bottom shunt are at the same electric potential. Below the bottom shunt is an insulator that is bolted to a bottom plate made of non-magnetic stainless steel. Two O-rings are used to seal the insulator and the bottom shunt and the bottom plate. The side dark space shield is bolted on the bottom plate. A metal tubing is welded to the bottom plate. On top of the dark space shield is a metal top shield. The top shield, side shield, bottom plate, and metal tubing are all connected to ground potential. All the parts are held together into an integrated magnetron body using bolts as illustrated.

The exemplary sputtering magnetron is a profile of a circular magnetron. The dimensions of the magnets depend on the size of the target to be sputtered. For an exemplary sputtering target of 50.8 mm diameter, the center magnet has a preferred diameter of 6-20 mm and the side ring-shaped magnet has a preferred inner diameter of 34-48 mm and outer diameter of 38-51 mm. For an exemplary sputtering target of 76.2 mm diameter, the center magnet has a preferred diameter of 6-30 mm and the side ring-shaped magnet has a preferred inner diameter of 50-70 mm and outer diameter of 58-76 mm. There are many possible designs of the magnet assembly, which can be practiced by a person with knowledge of magnetron sputtering. The spirit of this invention is to use magnetic steel as an outside shield to shunt leaking secondary magnetic flux out of the dark space shield and prevent secondary plasma.

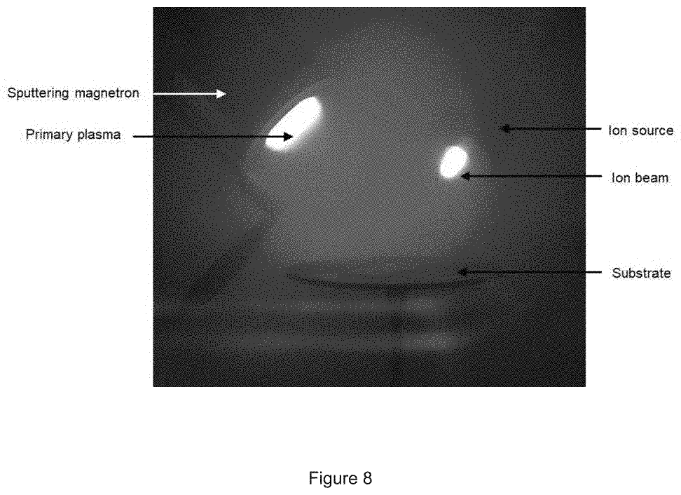

The discharge image of an exemplary sputtering magnetron and an ion source can be observed in FIG. 8. No secondary plasma is observed around the dark space shield. Hence, this invention effectively eliminates secondary plasma. A sputtering magnetron disclosed in this invention is particularly suitable for operating with other plasma sources like ion sources.

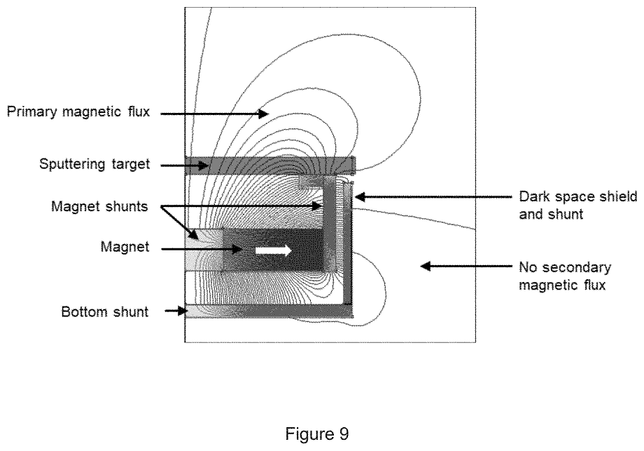

Another preferred embodiment of a magnet assembly in a circular sputtering magnetron can be observed in FIG. 9. There is only a primary magnetic flux, above a sputtering target, being created by a magnet assembly. The magnet assembly includes a magnet with N-S polarity in horizontal direction, two magnet shunts at the two ends of the magnet, a dark space shield, and a bottom shunt. All the shunts and the dark space shield are made of magnetic steel such as stainless steel 400 series and carbon steel. No substantial secondary magnetic flux exists outside the shield to effectively confine electrons around the shield. A complete sputtering magnetron based on this preferred embodiment of the magnet assembly also includes other components such as O-rings for sealing vacuum and water, vacuum feedthrough, cathode body, etc., as described previously.

While various embodiments have been disclosed, it should be appreciated that other variations may be employed. For example; specific magnet and shunt quantities and shapes may be varied although some of the desired benefits may not be realized. Additionally, the cathode body, insulator, base plate, and vacuum tubing may be varied, although certain advantages may not be achieved. Furthermore, each of the features may be interchanged and intermixed between any and ail of the disclosed embodiments. Changes and modifications are not to be regarded as a departure from the spirit or the scope of the present invention.

While operating the sputtering magnetron with an ion source has been disclosed, using the sputtering magnetron with other plasma sources for other applications is not to be regarded as a departure from the spirit or the scope of the present invention.

The invention claimed is:

1. A sputter magnetron apparatus comprising:
(a) a set of magnet assembly that includes a center magnet and a side magnet, which work together to generate a primary magnetic field above a sputter target to effectively confine electrons during sputter discharge;
(b) a set of side dark space shield that is made of magnetic metal, which shunts a secondary magnetic flux leaking from side to an extent to prevent the generation of a secondary plasma around the dark space shield;
(c) A bottom shunt that is adjacent to the dark space shield from the side.

2. The apparatus of claim 1, wherein the sputter magnetron has a circular shape and the dark space shield has a circular hollow cylinder shape. At least part of the dark space shield is made of a magnetic metal that can shunt side magnetic flux.

3. The apparatus of claim 1, wherein the sputter magnetron has a rectangular shape and the dark space shield consists of at least four sides. At least one side or part of one is made of magnetic metal that can shunt side magnetic flux.

4. The apparatus of claim 1, further comprising a single ion beam, with ions being substantially uniformly distributed around the emission axis when viewed in cross-section, emitted through the outlet opening along the emission axis.

5. The sputter magnetron apparatus of claim 1 operates simultaneously with another plasma source that is excited with an electric potential substantially different from the magnetron potential.

6. The apparatus of claim 5, wherein the sputter magnetron operates simultaneously with another plasma source to deposit thin films.
